(19) United States
(12) Patent Application Publication
(10) Pub. No.: US 2025/0219641 A1
(43) Pub. Date: Jul. 3, 2025

(54) SIGNAL DISTRIBUTION BOOSTER CIRCUIT AND METHOD

(71) Applicant: TAIWAN SEMICONDUCTOR MANUFACTURING COMPANY, LTD., Hsinchu (TW)

(72) Inventors: Tongqing BAI, Hsinchu (TW); Wei Wing MAR, Hsinchu (TW); Shankar KANADE, Hsinchu (TW); Aditya Narayan GAYATRI, Hsinchu (TW); Krishna Jivraj KHAIRMAR, Hsinchu (TW)

(21) Appl. No.: 18/635,892

(22) Filed: Apr. 15, 2024

Related U.S. Application Data
(60) Provisional application No. 63/617,387, filed on Jan. 3, 2024.

(51) Int. Cl. H03K 19/0185; H03K 5/003; H03K 5/134; H03K 19/20

(52) U.S. Cl. CPC H03K 19/018521; H03K 5/003; H03K 5/134; H03K 19/20

(57) ABSTRACT

A circuit includes a signal node configured to receive a first control signal, a delay stage coupled to the signal node and configured to output a first booster signal responsive to the first control signal, and a boost stage coupled to the signal node and the delay stage. The boost stage includes a pull-up circuit including a first PMOS transistor configured to couple the signal node to a power supply voltage node responsive to the first booster signal and a pull-down circuit including a first NMOS transistor configured to couple the signal node to a reference voltage node responsive to the first booster signal.

### PRIORITY CLAIM

The present application claims the priority of U.S. Provisional Application No. 63/617,387, filed Jan. 3, 2024, which is incorporated herein by reference in its entirety.

### BACKGROUND

In many integrated circuit (IC) applications, a control or other signal is output from a source circuit such as a control circuit and routed to multiple targets. In some cases, e.g., those in which a large number of circuits are targeted, distributing the signal relies on long routing paths that can compromise the integrity of the delivered signal. One example is a memory circuit in which an enable signal is distributed from a control circuit to multiple local input/output (LIO) circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are schematic diagrams of signal distribution circuits, in accordance with some embodiments.

FIGS. 2A and 2B are schematic diagrams of signal distribution circuits, in accordance with some embodiments.

FIG. 3 is a schematic diagram of a signal distribution circuit, in accordance with some embodiments.

FIGS. 4A and 4B are diagrams of signal distribution circuit operating parameters, in accordance with some embodiments.

FIG. 5 is a schematic diagram of a signal distribution circuit, in accordance with some embodiments.

FIG. 6 is a schematic diagram of a signal distribution circuit, in accordance with some embodiments.

FIG. 7 is a flowchart of a method of operating a booster circuit, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, a booster circuit and method include a delay stage configured to output a booster signal responsive to a first control signal received at a signal node, and a boost stage including pull-up and pull-down circuits configured to couple the signal node to respective power supply and reference voltage nodes responsive to the booster signal. In some embodiments, the booster circuit is included in a signal distribution circuit in which a driver is configured to output the first control signal and a second control signal at first ends of first and second signal lines, and the signal node is coupled to a second end of the first signal line and to a buffer coupled to a second end of the second signal line.

By including pull-up and pull-down circuits configured to control the signal node responsive to the first control signal, the booster circuit is capable of improving the integrity of the first signal and thereby the integrity of the second control signal between the first and second ends of the second signal line by causing the buffer to drive the second end of the second signal line responsive to the first control signal. In some embodiments, the booster circuit is further configured, e.g., by including an inhibit circuit, to avoid contention between the control circuit and buffer during a power-on sequence and/or during a continuous operation mode, e.g., high-speed operation including control signals having short pulse widths.

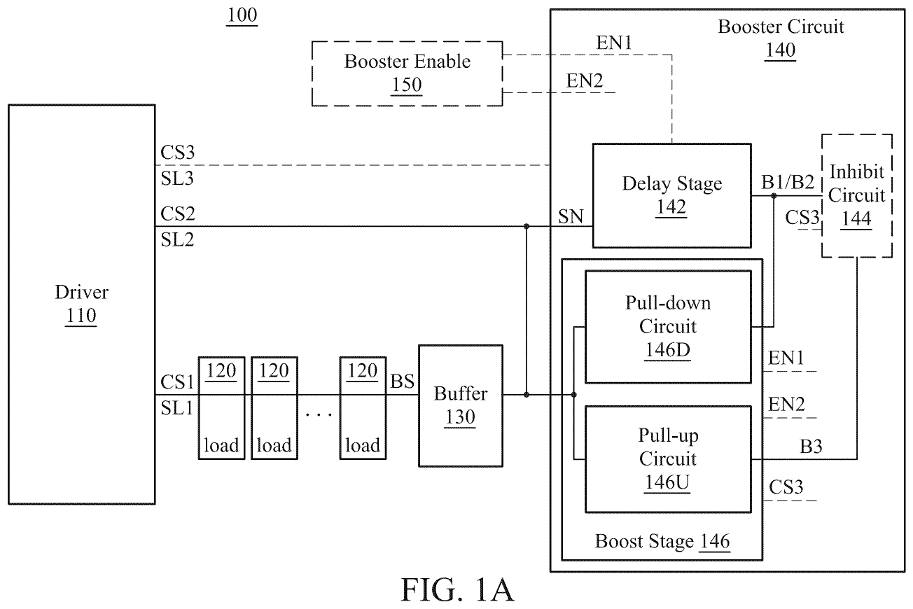

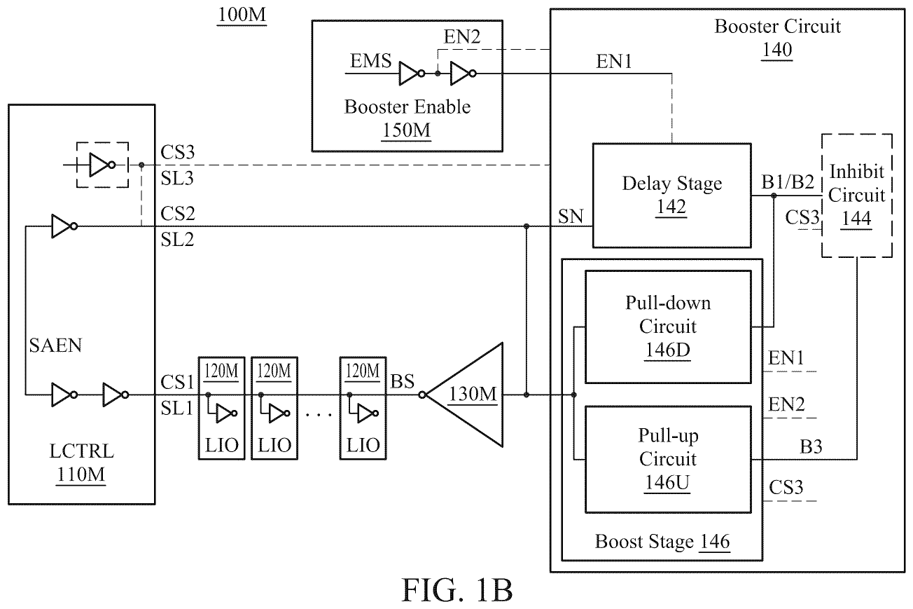

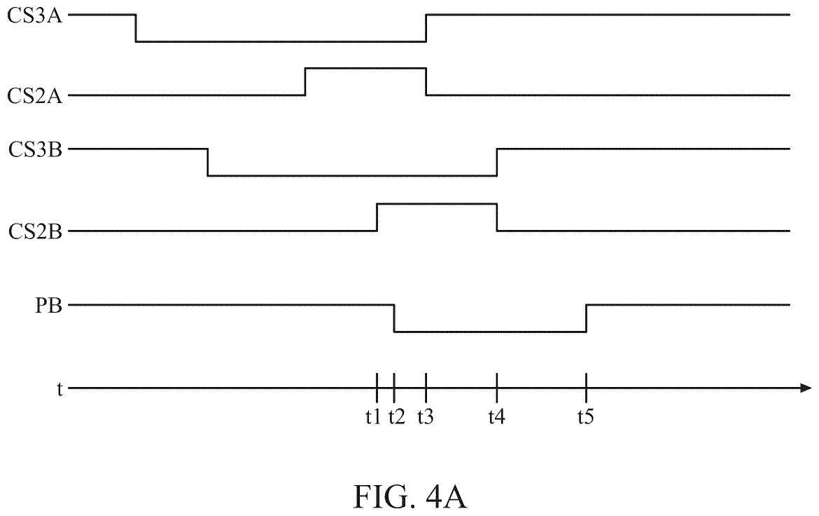

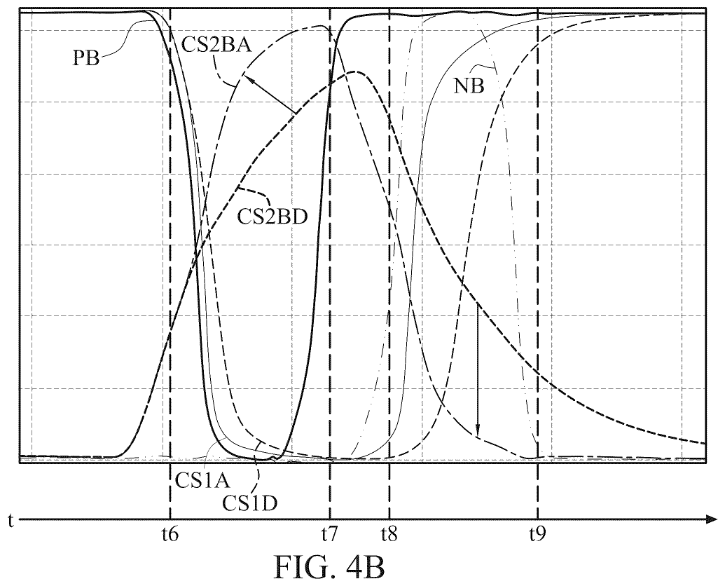

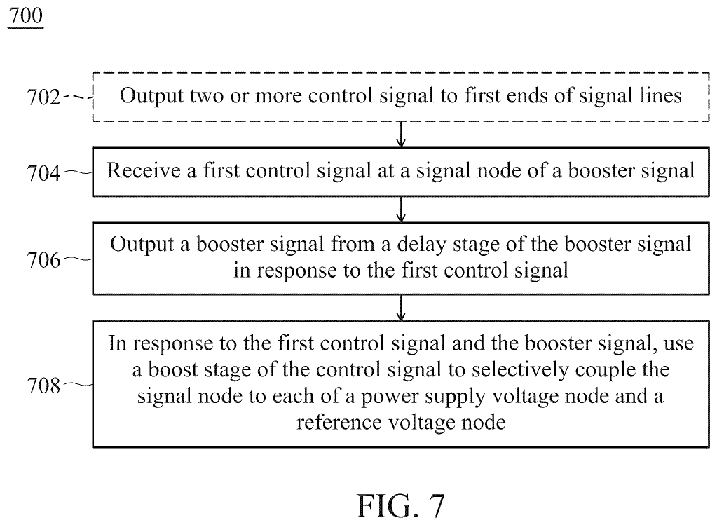

In accordance with various embodiments, each of FIGS. 1A-3, 5, and 6 is a schematic diagram of a signal distribution circuit 100, 100M, 200A, 200B, 300, 500, or 600 including a corresponding booster circuit 140, 240A, 240B, 340, 540, or 640, FIGS. 4A and 4B are diagrams of signal distribution circuit operating parameters in accordance with some embodiments, and FIG. 7 is a flowchart of a method of operating a booster circuit, in accordance with some embodiments.

In some embodiments, one or more of booster circuits 140, 240A, 240B, 340, 540, or 640 or signal distribution circuits 100, 100M, 200A, 200B, 300, 500, or 600 is some or all of an integrated circuit (IC). In some embodiments, one or more of booster circuits 140, 240A, 240B, 340, 540, or 640 or signal distribution circuits 100, 100M, 200A, 200B, 300, 500, or 600 is included in another IC circuit, e.g., a digital circuit, an analog circuit, and/or a memory circuit.

FIGS. 1A-6 are simplified for the purpose of illustration. In some embodiments, one or more of circuits 100, 100M, 200A, 200B, 300, 500, or 600 includes features in addition to those depicted in FIGS. 1A-6, e.g., a global control circuit configured to generate one or more control and/or enable signals including and/or in addition to those discussed below. Circuit elements depicted in FIGS. 1A-6 include corresponding input and output terminals that are not labeled for the purpose of clarity.

FIGS. 1A and 1B are schematic diagrams of respective signal distribution circuits 100 and 100M, in accordance with some embodiments. Signal distribution circuit 100 corresponds to a generalized embodiment including booster circuit 140, and signal distribution circuit 100M corresponds to a memory circuit embodiment including booster circuit 140, as discussed below. In some embodiments, as discussed below, one or both of signal distribution circuit 100 or 100M includes one of booster circuits 240A, 240B, 340, 540, or 640 instead of booster circuit 140.

Signal distribution circuit 100, also referred to as circuit 100 in some embodiments, includes a driver 110, load circuits 120, a buffer 130, booster circuit 140, a booster enable source 150 in some embodiments, and signal lines SL1, SL2, and in some embodiments SL3. Driver 110 is coupled to first ends of each of signal lines SL1, SL2, and, if present, SL3. Buffer 130 is coupled to a second end of signal line SL1, and load circuits 120 are coupled to signal line SL1 between driver 110 and buffer 130. Booster circuit 140 is coupled to second ends of signal line SL2 and, if present, signal line SL3.

Two or more circuit elements are considered to be coupled based on a direct electrical connection or an electrical connection that includes one or more additional circuit elements and is thereby capable of being controlled, e.g., made resistive or open by one or more transistors or other switching devices.

Driver 110, also referred to as control circuit 110 in some embodiments, is an electronic circuit, e.g., an IC, configured to output, from corresponding output terminals, control signal CS1 to the first end of signal line SL1, control signal CS2 to the first end of signal line SL2, and in some embodiments control signal CS3 to signal line SL3.

A control signal, e.g., control signal CS1-CS3, is an electronic signal including transitions between high and low voltage levels, e.g., corresponding to high and low logic levels. A high voltage or logic level corresponds to a voltage within a predefined range of a power supply voltage level, e.g., a VDD voltage level, and a low voltage or logic level corresponds to a voltage within a predefined range of a reference voltage level, e.g., a VSS or ground voltage level. Control signal timing is affected by a rate at which the control signal transitions between low and high voltage levels, also referred to as a slew rate in some embodiments, a given signal transition thereby corresponding to a transition time during which a signal voltage is slewing between the high and low voltage levels.

Driver 110 is configured to generate control signals CS1 and CS2 including some or all of the transitions synchronized to each other. Transitions are considered to be synchronized to each other by including overlapping transition times or transition times occurring within a predetermined time range, also referred to as a same time in some embodiments.

In some embodiments, the transitions are considered to be synchronized to each other based on each of control signals CS1 and CS2 including, at the same time, a positive transition from low to high voltage levels or a negative transition from high to low voltage levels. In some embodiments, the transitions are considered to be synchronized to each other based on one of control signals CS1 or CS2 including a positive transition and the other of control signals CS1 or CS2 including a negative transition at the same time.

In some embodiments, driver 110 is configured to generate each of control signals CS1 and CS2 including a series of pulses, each pulse having a pulse width corresponding to first and second transitions. The first and second transitions of control signal CS1 are synchronized to the first and second transitions of control signal CS2 such that control signals CS1 and CS2 are either complementary or synchronized, e.g., identical, pulsed signals.

In some embodiments, driver 110 is configured to generate control signal CS3 including at least one transition synchronized to the second transition of one or both of control signals CS1 or CS2. In some embodiments, driver 110 is configured to generate control signal CS3 complementary or synchronized to one or both of control signal CS1 or CS2 over a given time period or throughout an entirety of a powered-on state of circuit 100.

Buffer 130 is an electronic circuit, e.g., an IC, configured to output a signal BS, also referred to as a boosted signal BS in some embodiments, from an output terminal to the second end of signal line SL1 responsive to a voltage level received at an input terminal from the second end of signal line SL2, the voltage level corresponding to control signal CS2 propagated across signal line SL2 from driver 110 and boosted by booster circuit 140, as discussed below.

Driver 110 and buffer 130 are configured to output control signals CS1 and CS2 and signal BS coordinated with each other such that control signal CS1 and signal BS are considered to be in phase with each other, ignoring timing effects of parasitic resistance and capacitance of signal lines SL1 and SL2. In some embodiments, driver 110 is configured to output control signals CS1 and CS2 as complementary signals and buffer 130 includes inverting logic, e.g., an inverter. In some embodiments, driver 110 is configured to output control signals CS1 and CS2 as synchronized signals and buffer 130 includes non-inverting logic, e.g., an amplifier.

Each of signal lines SL1-SL3 includes one or more elongated volumes of conductive material, e.g., one or more metals such as copper, substantially surrounded by one or more volumes of insulating material, e.g., silicon dioxide, and extending between the first and second ends. A given signal line is thereby characterized by a distributed parasitic resistance and capacitance such that total resistance and capacitance values increase as a total length of the one or more elongated volumes of the signal line increases. Capacitance values are affected by signal line geometry relative to nearby structures such as other conductive lines, and resistance values are affected by conductive material type and signal line geometry, e.g., by decreasing as cross-sectional area increases.

In some embodiments, two or more of signal lines SL1-SL3 include the same conductive material(s) and have equal cross-sectional areas and thereby equal total resistance values for a given signal line length. In some embodiments, the two or more of signal lines SL1-SL3 are located in a same metal layer of an IC, e.g., a first metal layer.

In some embodiments, signal lines SL2 and/or SL3, if present, include conductive material(s) different from signal line SL1 conductive material(s) and/or have cross-sectional area(s) greater than that of signal line SL1 such that signal line SL1 has a greater resistance value than that/those of signal lines SL2 and/or SL3 for a given signal line length. In some embodiments, signal line SL1 is located in a lower metal layer of an IC, e.g., the first metal layer, relative to one or more upper metal layers of signal lines SL2 and/or SL3, e.g., a third metal layer, and the metal lines in each of the lower and upper layers extend in a same direction perpendicular to a metal line direction of an intermediate metal layer, e.g., a second metal layer.

A given signal, e.g., control signal CS1-CS3, propagated from the first end to the second end of the corresponding signal line incurs a loss of signal integrity, e.g., signal delay, attenuation, waveform, and/or slew rate degradation, that increases as the total resistance and capacitance values increase. In some embodiments, one or more design specifications based on the integrity of the given signal are included in defining total resistance and/or capacitance limits, and thereby a maximum length, of the corresponding signal line.

In some embodiments, an end of a signal line, as used herein, refers to a position along the signal line other than a physical end of the signal line, e.g., a position corresponding to an end of a portion of the signal line along which a corresponding one of control signals CS1-CS3 is propagated in accordance with the discussion herein.

Load circuits 120 are one or more electronic circuits, e.g., ICs, including input terminals configured to receive, from signal line SL1, a combination of control signal CS1 output from driver 110 to the first end of signal line SL1 and signal BS output from buffer 130 to the second end of signal line SL1.

In the embodiment depicted in FIG. 1A, load circuits 120 are instances of a plurality of individual circuits distributed along signal line SL1, each including a single input terminal. In some embodiments, one or more instances of load circuits 120 include more than one input terminal distributed along signal line SL1. In some embodiments, load circuits 120 represent a single circuit including a plurality of input terminals distributed along signal line SL1.

Based on the presence of the input terminals of load circuits 120, signal line SL1 has distributed and total capacitance values greater than that of a similarly configured and equally long signal line that does not include input terminals corresponding to some or all of those of load circuits 120. In the embodiments depicted in FIGS. 1A and 1B, signal lines SL1 and SL2 have substantially equal lengths, and signal line SL1 thereby has a total capacitance value greater than that of signal line SL2 based on the presence of load circuits 120. In some embodiments, signal lines SL1 and SL2 have unequal lengths, and signal line SL1 has a total capacitance value greater than that of signal line SL2 based on the presence of load circuits 120.

Booster circuit 140 is an electronic circuit, e.g., an IC, including a delay stage 142, an inhibit circuit 144 in some embodiments, and a boost stage 146. Each of delay stage 142 and boost stage 146 is coupled to the second end of signal line SL2 and the input terminal of buffer 130 through a node SN, also referred to as signal node SN in some embodiments.

Booster enable source 150, if present, is an electronic circuit and/or signal path(s) configured to, in operation, output a booster enable signal EN1 and in some embodiments a booster enable signal EN2 complementary to booster enable signal EN1. In some embodiments, booster enable signals EN1 and, if present, EN2 are referred to as enable signals EN1 and EN2 or activation signals EN1 and EN2. In some embodiments, booster enable source 150 is configured to output enable signals EN1 and, if present, EN2 based on a received signal, e.g., a global enable signal of circuit 100.

In the embodiment depicted in FIG. 1A, circuit 100 includes booster enable source 150 separate from booster circuit 140. In some embodiments, some or all of booster enable source 150 is external to circuit 100 or included in booster circuit 140.

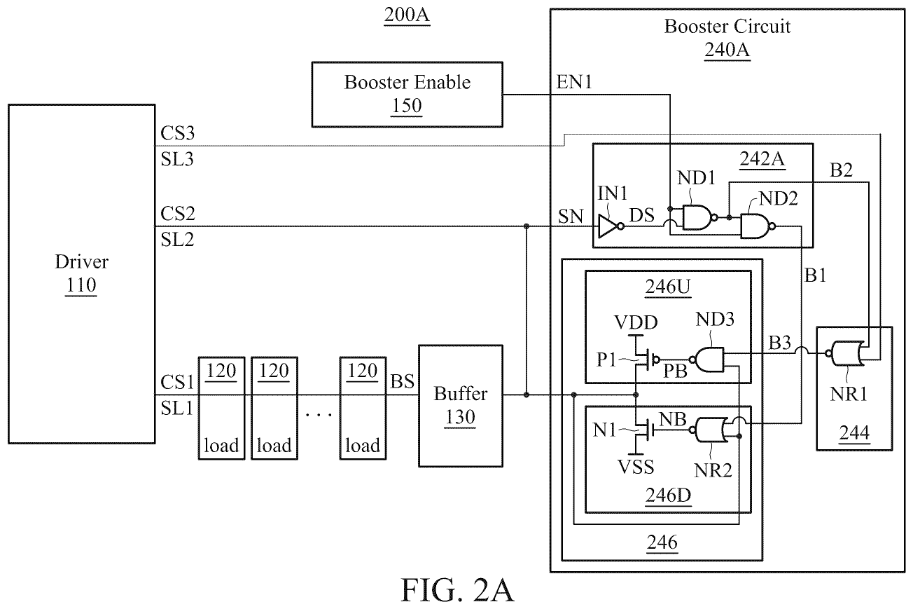

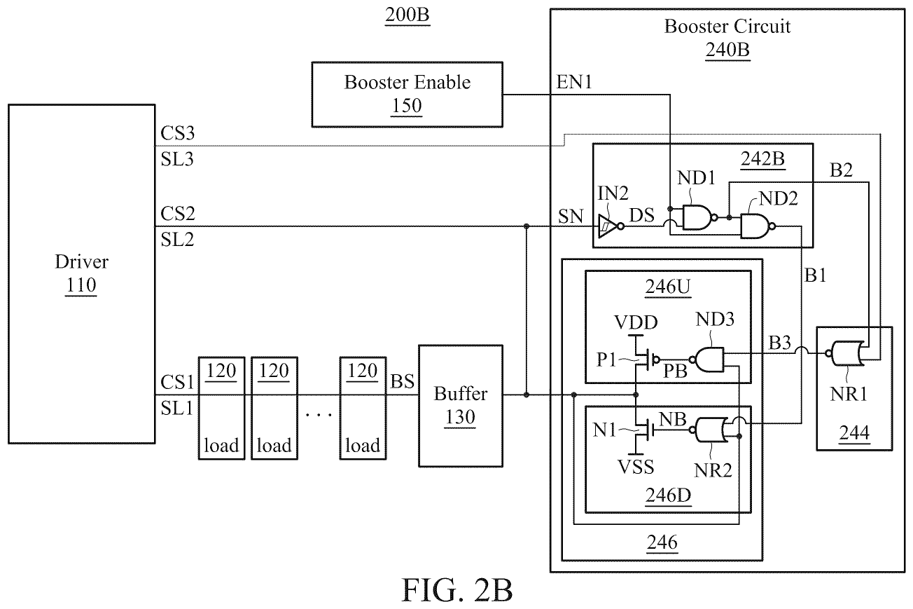

In some embodiments, circuit 100 is configured to operate with booster circuit 140 being in an activated or deactivated state responsive to the high or low logic level(s) of enable signal EN1 and, if present EN2. In each of the embodiments discussed below with respect to FIGS. 2A-6, the corresponding circuit 200A, 200B, 300, 500, or 600 (usable as circuit 100) is configured to operate with the corresponding booster circuit 240A, 240B, 340, 540, or 640 (usable as booster circuit 140) in the activated state based on booster enable source 150 outputting enable signal EN1 having the low logic level and, if present, enable signal EN2 having the high logic level, and to operate with the corresponding booster circuit 240A, 240B, 340, 540, or 640 in the deactivated state based on booster enable source 150 outputting enable signal EN1 having the high logic level and, if present, enable signal EN2 having the low logic level.

Circuit 100 otherwise configured to operate with booster circuit 140 in the activated and deactivated states responsive to enable signal EN1 and, if present, EN2 are within the scope of the present disclosure.

Each of enable signals EN1 and EN2 is configured to maintain one of the high or low logic levels, e.g., corresponding to the activated or deactivated state, for a period sufficiently long to allow circuit 100 to execute a power-on sequence and/or a continuous operating mode during which control signals CS1-CS3 include multiple voltage transitions corresponding to an operating frequency of circuit 100.

As the operating frequency of circuit 100 increases, the criticality of the signal integrity of control signals CS1-CS3 with respect to signal paths SL1-SL3 increases. In some embodiments, circuit 100 is configured to have a continuous operating frequency ranging from 1 megahertz (MHz) to 500 gigahertz (GHz). In some embodiments, circuit 100 is configured to have a continuous operating frequency ranging from 100 GHz to 400 GHz.

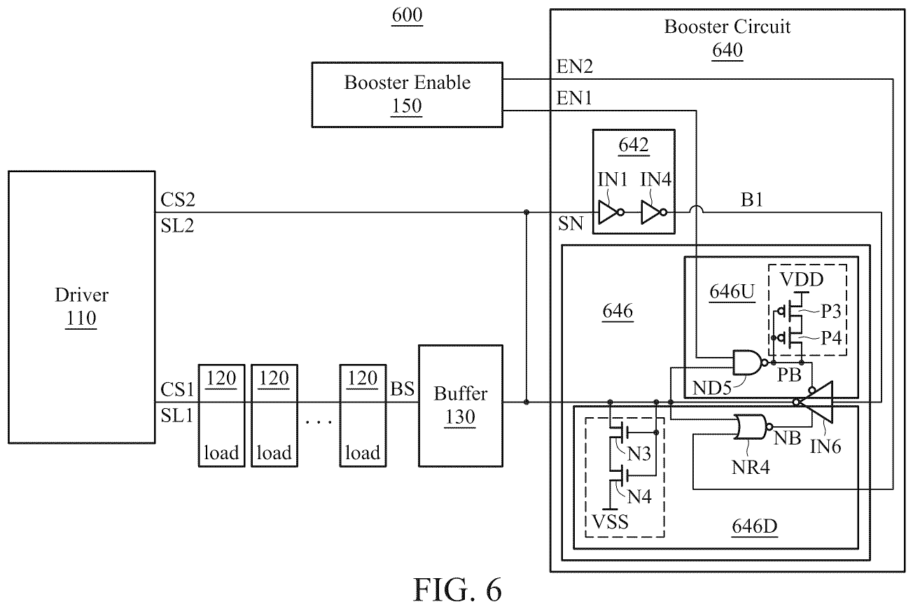

Delay stage 142 includes an arrangement of one or more logic devices configured to, in operation, output at least one booster signal B1 including a transition responsive to and delayed from a corresponding transition in control signal CS2 received at node SN. In some embodiments, delay stage 142 is configured to output booster signal B1 having the delayed transition a polarity opposite that of the control signal CS2 transition, e.g., as discussed below with respect to delay stages 242A, 242B, and 542 and FIGS. 2A-5. In some embodiments, delay stage 142 is configured to output booster signal B1 having the delayed transition the same polarity as the control signal CS2 transition, e.g., as discussed below with respect to delay stage 642 and FIG. 6.

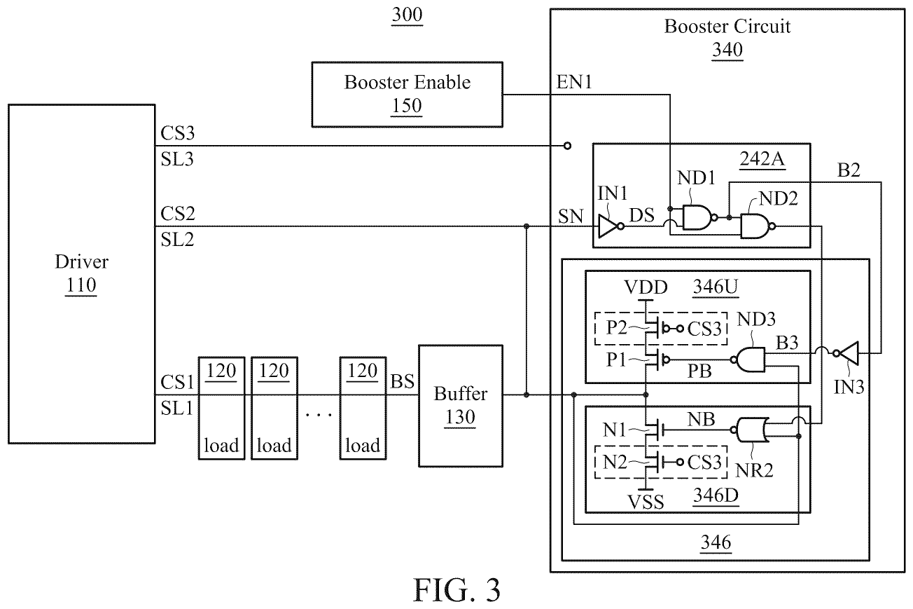

In some embodiments, delay stage 142 is configured to output a booster signal B2 complementary to booster signal B1, e.g., as discussed below with respect to delay stages 242A and 242B and FIGS. 2A-3.

In some embodiments, delay stage 142 is configured to, in operation, receive enable signal EN1, and the one or more logic devices are configured to output booster signals B1 and, if present, B2 responsive to enable signal EN1. In some embodiments, delay stage 142 is configured to, responsive to one of the high or low logic level of enable signal EN1, output booster signals B1 and, if present, B2 having high or low logic level steady states, and responsive to the other of the high or low logic level of enable signal EN1, output booster signals B1 and, if present, B2 responsive to the logic levels of control signal CS2.

In some embodiments, delay stage 142 is not configured to receive enable signal EN1.

In some embodiments, circuit 100 does not include booster enable source 150, and delay stage 142 is configured to output booster signals B1 and, if present, B2 responsive to the logic levels of control signal CS2 throughout an entirety of a power-on sequence and powered-on state of circuit 100.

In some embodiments, delay stage 142 includes one of delay stage 242A, 242B, 542, or 642 discussed below with respect to FIGS. 2A-6.

Boost stage 146 includes logic devices arranged as a pull-down circuit 146D and a pull-up circuit 146U, each coupled to node SN. Pull-down circuit 146D includes an NMOS transistor and a logic gate (not shown in FIG. 1A) configured to, in operation, couple node SN to a reference voltage node (not shown in FIG. 1A) configured to carry the reference voltage level, e.g., VSS, responsive to control signal CS2 and booster signal B1. Pull-up circuit 146U includes a PMOS transistor and a logic gate (not shown in FIG. 1A) configured to, in operation, couple node SN to a power supply voltage node (not shown in FIG. 1A) configured to carry the power supply voltage level, e.g., VDD, responsive to control signal CS2 and booster signal B1 or B2.

Each of pull-down circuit 146D and pull-up circuit 146U is configured to, in operation, couple node SN to the respective one of the reference or power supply voltage node responsive to a control signal CS2 transition, and to decouple node SN from the respective one of the reference or power supply voltage node responsive to a corresponding booster signal B1 or B2 transition delayed from the control signal CS2 transition.

In some embodiments, one of pull-down circuit 146D or pull-up circuit 146U is configured to, in operation, receive control signal CS3 and to decouple node SN from the respective one of the reference or power supply voltage node responsive to a corresponding control signal CS3 transition synchronized to the control signal CS2 transition such that the pull-down circuit 146D or pull-up circuit 146U is thereby configured to decouple node SN from the respective one of the reference or power supply voltage node at a time different from the time corresponding to the delayed booster signal B1/B2 transition.

In such embodiments, in cases in which the delay between the control signal CS2 and booster signal B1 or B2 is greater than a pulse width of control signals CS1 and CS2, boost stage 146 is configured to decouple node SN from the respective one of the reference or power supply voltage node before the end of the control signal CS1 pulse, thereby acting to prevent buffer 130 from contending with driver 110 for control of signal line SL1.

In some embodiments, pull-up circuit 146 is configured to receive enable signal EN1 and to couple and decouple node SN to and from the power supply voltage node further responsive to enable signal EN1. In some embodiments, pull-up circuit 146 is configured to receive enable signal EN2 and to couple and decouple node SN to and from the reference voltage node further responsive to enable signal EN2.

In some embodiments, boost stage 146 includes one of boost stage 246, 346, 546, or 646 including respective pull-down circuit 246D, 346D, 546D, or 646D and pull-up circuit 246U, 346U, 546U, or 646U discussed below with respect to FIGS. 2A-6.

In some embodiments, inhibit circuit 144 includes one or more logic devices configured to, in operation, receive control signal CS3 and booster signal B2, and output a booster signal B3 to pull-up circuit 146U responsive to control signal CS3 and booster signal B2, whereby pull-up circuit 146U is configured to couple and decouple node SN to and from the power supply voltage node responsive to control signal CS3 and booster signal B2. In some embodiments, inhibit circuit 144 includes inhibit circuit 244 discussed below with respect to FIGS. 2A and 2B.

In some embodiments, driver 110 is configured to, in operation, generate each of control signals CS1-CS2 including identical or complementary pulses having leading and trailing pulse edges, the control signal CS3 pulse thereby having a pulse width greater than that of the pulses of control signals CS1 and CS2. In some embodiments, driver 110 is configured to, in operation, generate each of control signals CS1 and CS2 including identical or complementary pulses having leading and trailing pulse edges, and control signal CS3 including a pulse having a leading edge preceding or following those of control signals CS1 and CS2 and a trailing pulse edge synchronized to those of control signals CS1 and CS2, the control signal CS3 pulse thereby having a corresponding pulse width greater or smaller than that of the pulses of control signals CS1 and CS2.

In some embodiments, control signal CS3 pulses correspond to a first logic level, time periods before and after pulses correspond to a second logic level, and one or both of pull-up circuit 146U or pull-down circuit 146D is configured to decouple node NS from the corresponding power supply or reference voltage node responsive to the second logic level of control signal CS3 based on receiving control signal CS3 or one of booster signals B1-B3 as discussed above. In some embodiments, control signal CS3 is configured to, in operation, have the second logic level during a power-on sequence of circuit 100 whereby node SN is decoupled from each of the power supply and reference voltage nodes during the power-on sequence.

Booster circuit 140 including delay stage 142, inhibit circuit 144 in some embodiments, and boost stage 146 is thereby configured to, in operation, selectively couple node SN to one of the reference or power supply voltage node responsive to control signal CS2 and decouple node SN from the one of the reference or power supply voltage node responsive to booster signals B1 and, if present, B2, each being based on control signal CS2.

Booster circuit 140 is thereby capable of being included in a signal distribution circuit, e.g., circuit 100, in which a driver, e.g., driver 110, is configured to output control signals CS1 and CS2 at first ends of first and second signal lines, e.g., signal lines SL1 and SL2, and node SN is coupled to a second end of the first signal line and to a buffer, e.g., buffer 130, coupled to the second end of the second signal line. By including pull-down and pull-up circuits 146D and 146U configured to control node SN responsive to control signal CS2, booster circuit 140 is capable of improving the integrity of control signal CS2 at the second end of signal line SL2, thereby improving the ability of the buffer to drive the second end of signal line SL1 compared to approaches that do not include booster circuit 140.

In some embodiments, e.g., those including pull-down circuit 146D and/or pull-up circuit 146U configured to control node SN further responsive to control signal CS3 as discussed above, booster circuit 140 is capable of avoiding lockup of the circuit, e.g., circuit 100, during power-on sequences and/or during a continuous operation mode by preventing booster circuit 140 from causing the buffer to contend with the driver for control of the corresponding signal line, e.g., signal line SL1.

In some embodiments, booster circuit 140 is capable of being selectively activated responsive to enable signal EN1 and, if present, EN2, whereby the benefits discussed above are optionally included in the operation of a circuit, e.g., circuit 100, that includes booster circuit 140.

In some embodiments, booster circuit 140 includes one of booster circuit 240A, 240B, 340, 540, or 640 discussed below with respect to FIGS. 2A-6.

In the embodiment depicted in FIG. 1B, memory circuit 100M, also referred to as circuit 100M or static random-access memory (SRAM) circuit 100M in some embodiments, is usable as circuit 100 discussed above with respect to FIG. 1A. Circuit 100M includes a local control circuit 110M usable as driver 110, local input/output (LIO) circuits 120M usable as load circuits 120, inverter 130M usable as buffer 130, a booster enable source 150M usable as booster enable source 150, and booster circuit 140, each discussed above with respect to FIG. 1A.

Local control circuit 110M includes a pair of first inverters (not labeled) arranged in series and configured to receive a sense amplifier enable signal SAEN and to output control signal CS1 to signal line SL1 responsive to and in phase with (ignoring inverter switching delays) enable signal SAEN. A second inverter (not labeled) is configured to receive enable signal SAEN and output control signal CS2 to signal line SL2 responsive to and complementary to (other than inverter switching delays) enable signal SAEN.

Local control circuit 110M is thereby configured to, in operation, output control signals CS1 and CS2 as complementary signals based on enable signal SAEN, and local control circuit 110M and inverter 130M are thereby configured to output control signal CS1 and signal BS in phase with each other.

In some embodiments, the second inverter is configured to, in operation, output each of control signals CS2 and CS3 to the corresponding signal line SL2 or SL3 responsive to and complementary to enable signal SAEN.

In some embodiments, local control circuit 110M includes a third inverter (not labeled) configured to, in operation, output control signal CS3 to signal line SL3 responsive to an enable signal (not labeled) other than enable signal SAEN such that control signal CS3 includes a transition synchronized to a transition of control signal CS1, as discussed above with respect to circuit 100.

In some embodiments, control signal CS3 corresponds to a pre-charge enable signal corresponding to circuit 100M being configured to pre-charge one or more bit lines of a group of memory cells to a target voltage level, e.g., a power supply voltage level, as part of a read operation. In some embodiments, local control circuit 110M is configured to output control signals CS1 and CS3 including pulses having a same polarity, e.g., each pulse having the low logic level.

In some embodiments, local control circuit 110M includes an output terminal coupled to signal line SL1 positioned in a first metal layer of an IC, an output terminal coupled to signal line SL2 positioned in a third metal layer of the IC overlying the first metal layer, and in some embodiments, an output terminal coupled to signal line SL3 positioned in the third metal layer.

In some embodiments, circuit 100M is some or all of a memory macro, e.g., an SRAM macro including a global control circuit (not shown) in which local control circuit 110M is one instance LCTRL of multiple local control circuits LCTRL, each instance corresponding to one or more banks or arrays of memory cells, e.g., SRAM cells (not shown).

In some embodiments, enable signal SAEN corresponds to a global sense amplifier enable signal of memory circuit 100M and control signal CS1 is a local version of enable signal SAEN. Each LIO circuit corresponds to one or more rows or columns of memory cells and includes at least one sense amplifier (not shown) configured to, in a read operation, detect voltage or current levels output from the memory cells of the corresponding row(s) or column(s) responsive to a combination of control signal CS1 and signal BS received from signal line SL1. In some embodiments, circuit 100M is configured to execute the read operation synchronized to a pulse of control signal CS1, e.g., during a time period corresponding to the pulse width of the pulse of control signal CS1.

Booster enable source 150M includes a pair of inverters (not labeled) configured to, in operation, receive a signal EMS and output enable signal EN1 as a buffered version of signal EMS and, in some embodiments, enable signal EN2 as a buffered and inverted version of signal EMS.

Signal EMS is a global enable signal of circuit 100M configured to have the low logic level corresponding to activating booster circuit 140 and the high logic level corresponding to deactivating booster circuit 140 as discussed above. In some embodiments, circuit 100M is configured to generate control signals CS1 and CS2 having a first pulse width corresponding to signal EMS having the logic level corresponding to activating booster circuit 140, and to generate control signals CS1 and CS2 having a second pulse width greater than the first pulse width corresponding to signal EMS having the logic level corresponding to deactivating booster circuit 140. In some embodiments, signal EMS is received from a source external to circuit 100M.

In some embodiments, signal EMS has the low or high logic level based on an extra margin adjustment (EMA) signal, e.g., received from an EMA pin. In some embodiments, signal EMS has the low or high logic level based on a configuration of circuit 100M, e.g., a number of memory cells, columns, banks, or the like. In some embodiments, signal EMS is referred to as a chicken bit.

By the configuration discussed above, circuit 100M including booster circuit 140 is capable of realizing the benefits discussed above with respect to circuit 100 as a memory circuit embodiment of circuit 100 in which control signals CS1, CS2, and, if present, CS3 are generated as part of read operations of circuit 100M. By including booster circuit 140 configured to perform the operations discussed above by leveraging signals otherwise used in read operations, circuit 100M is capable of realizing the benefits with little or no impact on an overall area occupied by circuit 100M.

FIGS. 2A and 2B are schematic diagrams of respective signal distribution circuits 200A and 200B, in accordance with some embodiments. Each of signal distribution circuits 200A and 200B, also referred to as circuits 200A and 200B in some embodiments, is usable as circuit 100 or 100M and includes driver 110, load circuits 120, buffer 130, and booster enable source 150, each discussed above with respect to FIGS. 1A and 1B.

Circuit 200A also includes booster circuit 240A including delay stage 242A, inhibit circuit 244, and boost stage 246, usable as booster circuit 140 including delay stage 142, inhibit circuit 144, and boost stage 146 discussed above with respect to FIGS. 1A and 1B. Circuit 200B also includes booster circuit 240B including delay stage 242B, inhibit circuit 244, and boost stage 246, usable as booster circuit 140 including delay stage 142, inhibit circuit 144, and boost stage 146 discussed above with respect to FIGS. 1A and 1B.

As depicted in FIG. 2A, delay stage 242A includes an inverter IN1 and NAND gates ND1 and ND2. As depicted in FIG. 2B, delay stage 242B includes an inverter IN2 and NAND gates ND1 and ND2. Each of inverters IN1 and IN2 includes an input terminal coupled to node SN and thereby configured to receive control signal CS2 from the second end of signal line SL2.

Inverter IN1 of delay stage 242A includes a logic gate configured to, in operation, output a signal DS complementary to control signal CS2 received from the second end of signal line SL2. Inverter IN2 of delay stage 242B (or one of delay stages 542 or 642 discussed below) includes a Schmitt trigger configured to, in operation, output signal DS complementary to control signal CS2 received from the second end of signal line SL2.

By including the Schmitt trigger, inverter IN2 is configured to output signal DS having improved timing and reduced process-voltage-temperature (PVT) dependence compared to inverter IN1, but requires larger circuit area to implement based on more components and, in some embodiments, larger feature sizes to address yield challenges.

In each of delay stages 242A and 242B, NAND gate ND1 includes an input terminal configured to receive enable signal EN1 from booster enable source 150 and an input terminal coupled to the output terminal of the corresponding one of inverter IN1 or IN2, and is thereby configured to, in operation, output booster signal B2 on an output terminal responsive to enable signal EN1 and signal DS, and thereby responsive to control signal CS2.

In each of delay stages 242A and 242B, NAND gate ND2 includes an input terminal coupled to an output terminal of NAND gate ND1 and thereby configured to receive booster signal B2 and an input terminal configured to receive enable signal EN1 from booster enable source 150, and is thereby configured to, in operation, output booster signal B1 on an output terminal responsive to enable signal EN1 and booster signal B2.

Inhibit circuit 244 includes a NOR gate NR1 including an input terminal coupled to the output terminal of NAND gate ND1 and thereby configured to receive booster signal B2 and an input terminal configured to receive control signal CS3 from the second end of signal line SL3, and is thereby configured to output booster signal B3 on an output terminal responsive to booster signal B2 and control signal CS3.

As depicted in FIGS. 2A and 2B, boost stage 246 includes pull-up circuit 246U and pull-down circuit 246D, each coupled to node SN. Pull-up circuit 246U includes a PMOS transistor P1 coupled between node SN and a power supply voltage node VDD, and a NAND gate ND3 including an output terminal coupled to a gate of transistor P1, an input terminal coupled to the output terminal of NOR gate NR1, and an input terminal coupled to node SN. Pull-down circuit 246D includes an NMOS transistor N1 coupled between node SN and a reference voltage node VSS, and a NOR gate NR2 including an output terminal coupled to a gate of transistor N1, an input terminal coupled to the output terminal of NAND gate ND2, and an input terminal coupled to node SN.

NAND gate ND3 of pull-up circuit 246U is thereby configured to, in operation, output a boost signal PB to the gate of transistor P1 responsive to booster signal B3 received from NOR gate NR1 and control signal CS2 received from node SN, and transistor P1 is thereby configured to selectively couple and decouple node SN to and from power supply voltage node VDD responsive to boost signal PB.

NOR gate NR2 of pull-down circuit 246D is thereby configured to output a boost signal NB to the gate of transistor N1 responsive to booster signal B1 received from NAND gate ND2 and control signal CS2 received from node SN, and transistor N1 is thereby configured to selectively couple and decouple node SN to and from reference voltage node VSS responsive to boost signal NB.

In the embodiments depicted in FIGS. 2A and 2B, driver 100 is configured to, in operation, output control signals CS1-CS3 including trailing pulse edges synchronized with each other, the control signal CS2 pulse including the high logic level and the control signal CS3 pulse including the low logic level. In various embodiments, either the control signal CS1 pulse includes the low logic level and buffer 130 includes inverting logic, or the control signal CS1 pulse includes the high logic level and buffer 130 includes non-inverting logic.

Each of booster circuits 240A and 240B is thereby configured to, in operation, receive control signal CS2 at delay stage 242A or 242B and boost stage 246, control signal CS3 at inhibit circuit 244, and enable signal EN1 at delay stage 242A or 242B, and to control coupling and decoupling of node SN to and from power supply voltage node VDD using pull-up circuit 246U and to and from reference voltage node VSS using pull-down circuit 246D responsive to control signals CS2 and CS3 and enable signal EN1 in accordance with the discussion above with respect to circuits 100 and 100M and booster circuit 140.

Each of booster circuits 240A and 240B, as included in respective circuit 200A or 200B in some embodiments, is thereby configured to realize the benefits discussed above with respect to circuits 100 and 100M and booster circuit 140.

FIG. 3 is a schematic diagram of signal distribution circuit 300, in accordance with some embodiments. Signal distribution circuit 300, also referred to as circuit 300 in some embodiments, is usable as circuit 100 or 100M and includes driver 110, load circuits 120, buffer 130, and booster enable source 150, each discussed above with respect to FIGS. 1A and 1B.

Circuit 300 also includes booster circuit 340, usable as booster circuit 140, including delay stage 242A, discussed above with respect to FIGS. 2A and 2B, and boost stage 346, usable as boost stage 146 discussed above with respect to FIGS. 1A and 1B. In some embodiments, booster circuit 340 includes delay stage 242B, discussed above with respect to FIGS. 2A and 2B, instead of delay stage 242A.

As depicted in FIG. 3, boost stage 346 includes pull-up circuit 346U and pull-down circuit 346D, each coupled to node SN. Pull-up circuit 346U includes transistor P1 and NAND gate ND3, and pull-down circuit 346D includes transistor N1 and NOR gate NR2, each configured as discussed above with respect to FIGS. 1A and 1B.

In various embodiments, either pull-up circuit 346U also includes a PMOS transistor P2 coupled in series with transistor P1 between node SN and power supply voltage node VDD and including a gate configured to receive control signal CS3, or pull-down circuit 346D also includes an NMOS transistor N2 coupled in series with transistor N1 between node SN and reference voltage node VSS and including a gate configured to receive control signal CS3.

In the embodiment depicted in FIG. 3, transistor P2, if present, is positioned between transistor P1 and power supply voltage node VDD, and transistor N2, if present, is positioned between transistor N1 and reference voltage node VSS. In some embodiments, the one of transistor P2 or N2 is positioned between node NS and the corresponding one of transistor P1 or N1.

NAND gate ND3 and transistor P1 of pull-up circuit 346U are thereby configured to, in operation, selectively couple and decouple node SN to and from power supply voltage node VDD as discussed above with respect to FIGS. 2A and 2B, and transistor P2 is thereby configured to couple and decouple node SN to and from power supply voltage node VDD further responsive to control signal CS3.

NOR gate NR2 and transistor N1 are thereby configured to, in operation, selectively couple and decouple node SN to and from reference voltage node VSS as discussed above with respect to FIGS. 2A and 2B, and transistor N2 is thereby configured to couple and decouple node SN to and from reference voltage node VSS further responsive to control signal CS3.

In the embodiment depicted in FIG. 3, driver 100 is configured to output control signals CS1-CS3 including trailing pulse edges synchronized with each other, the control signal CS2 pulse including the high logic level and the control signal CS3 pulse including the low logic level corresponding to pull-up circuit 346U including transistor P2 or including the high logic level corresponding to pull-up circuit 346D including transistor N2. In various embodiments, either the control signal CS1 pulse includes the low logic level and buffer 130 includes inverting logic, or the control signal CS1 pulse includes the high logic level and buffer 130 includes non-inverting logic.

Booster circuit 340 is thereby configured to, in operation, receive control signal CS2 at delay stage 242A or 242B and boost stage 346, control signal CS3 at pull-up circuit 346U or pull-down circuit 346D of boost stage 346, and enable signal EN1 at delay stage 242A or 242B, and to control coupling and decoupling of node SN to and from power supply voltage node VDD using pull-up circuit 246U and to and from reference voltage node VSS using pull-down circuit 246D responsive to control signals CS2 and CS3 and enable signal EN1 in accordance with the discussion above with respect to circuits 100 and 100M and booster circuit 140.

Booster circuit 340, as included in circuit 300 in some embodiments, is thereby configured to realize the benefits discussed above with respect to circuits 100 and 100M and booster circuit 140.

Based on boost stage 346 including one of transistors P2 or N2 including the gate configured to receive control signal CS3 free from delays introduced by logic gates, e.g., NAND gate ND3 or NOR gate NR2, booster circuit 340 is further configured to decouple node SN from the corresponding one of power supply voltage node VDD or reference voltage node VSS prior to a time at which the corresponding one of transistor P1 or N1 would otherwise decouple node SN in cases in which the control signal CS1 and CS2 pulse width is less than the delay introduced by the logic gates of delay stage 242A or 242B and boost stage 346. Booster circuit 340 is thereby configured to, for short control signal pulse widths, avoid signal line contention between a driver and buffer, e.g., driver 110 and buffer 130 at first and second ends of signal line SL1, the buffer being controlled by the node SN voltage.

FIG. 4A depicts operating parameters of a signal distribution circuit, e.g., one of circuits 100, 100M, 200A, 200B, or 300 discussed above, in accordance with some embodiments.

FIG. 4A includes non-limiting examples of control signals CS2 and CS3 and boost signal PB, each discussed above, plotted over time t. In the embodiment depicted in FIG. 4A, control signal CS2 corresponds to an enable signal, e.g., a sense amplifier enable signal, (identical or complementary to control signal CS1, not depicted in FIG. 4A) including a pulse having the high logic level, and control signal CS3 corresponds to a signal, e.g., a pre-charge signal, including a pulse having the low logic level. The leading edge (first transition) of the control signal CS3 pulse precedes the leading edge (first transition) of the control signal CS2 pulse, and the trailing edges (second transitions) of the control signal CS2 and CS3 pulses are synchronized.

A signal CS3A represents control signal CS3 output to the first end of signal line SL3 from driver 110, a signal CS2A represents control signal CS2 output to the first end of signal line SL2 from driver 110, a signal CS3B represents control signal CS3 propagated to the second end of signal line SL3, and a signal CS2B represents control signal CS2 propagated to the second end of signal line SL2 and node SN.

A time t1 represents the leading edge of the signal CS2B pulse and a time t2 represents the leading edge of a boost signal PB pulse generated in response to the signal CS2B pulse leading edge in accordance with the configuration of (activated) control circuit 240A, 240B, or 340 discussed above.

Time t3 represents the trailing edges of the control signal CS2A and CS3A pulses, and time t4 represents the trailing edges of the control signal CS2B and CS3B pulses, a difference between times t3 and t4 thereby corresponding to a propagation delay of each of signal lines SL2 and SL3.

Time t5 represents the trailing edge of the boost signal PB pulse generated in response to booster signal B2 (not shown in FIG. 4) in accordance with the configuration of control circuits 240A, 240B, and 340 discussed above. Between times t2 and t5, boost signal PB having the low logic level causes transistor P1 to be switched on, thereby acting to couple node SN to power supply voltage node VDD, and after time t5, boost signal PB having the high logic level causes transistor P1 to be switched off.

In embodiments including control circuits 240A and 240B, transistor P1 alone is capable of coupling and decoupling node NS to and from power supply voltage node VDD, and a pulse width of the control signal CS2 pulse is sufficiently long that an entirety of the time boost signal PB has the low logic level corresponds to control signal CS1 having a same logic level as that of signal BS output from buffer 130 in response to boost signal PB.

In embodiments including control circuit 340 including boost stage 346 in which pull-up circuit 346U includes transistor P2 configured to receive control signal CS3 from the second end of signal line SL3, based on the trailing edge of the control signal CS3B pulse, transistor P2 is switched off at time t4 prior to time t5, thereby decoupling node NS from power supply voltage node VDD prior to the time at which node NS would otherwise be decoupled from power supply voltage node VDD, e.g., in embodiments including control circuit 200A or 200B, as discussed above with respect to FIG. 3.

FIG. 4B depicts operating parameters of a signal distribution circuit, e.g., one of circuits 100, 100M, 200A, 200B, or 300 discussed above or circuits 500 or 600 discussed below, in accordance with some embodiments.

FIG. 4B includes non-limiting examples of control signals CS1 and CS2 and boost signals PB and NB, each discussed above and below, plotted over time t. In the embodiment depicted in FIG. 4B, control signals CS1 and CS2 correspond to complementary enable signals, e.g., sense amplifier enable signals.

Signals CS1A and CS2BA represent control signals CS1 and CS2 (received at node NS) corresponding to enable signals EN1 and, if present, EN2 having the logic level(s) corresponding to the corresponding control circuit 140, 240A, 240B, 340, 540, or 640 being activated, and signals CS1D and CS2BD represent control signals CS1 and CS2 (received at node NS) corresponding to enable signals EN1 and, if present, EN2 having the logic level(s) corresponding to the corresponding control circuit 140, 240A, 240B, 340, 540, or 640 being deactivated. Boost signals PB and NB correspond to the activated state.

A time period between times t6 and t7 corresponds to pull-up boosting of node NS (corresponding to a positive transition of signals CS1A and CS1D) during which boost signal PB includes a pulse including the low logic level, boost signal NB maintains the low logic level, and a first arrow indicates a difference between control signal CS2BA in the activated state compared to control signal CS2BD in the deactivated state. Compared to control signal CS2BD, control signal CS2BA includes increased slew rate and pulse magnitude.

A time period between times t8 and t9 corresponds to pull-down boosting of node NS (corresponding to a negative transition of signals CS1A and CS1D) during which boost signal NB includes a pulse including the high logic level, boost signal PB maintains the high logic level, and a second arrow indicates a difference between control signal CS2BA in the activated state compared to control signal CS2BD in the deactivated state. Compared to control signal CS2BD, control signal CS2BA includes increased slew rate.

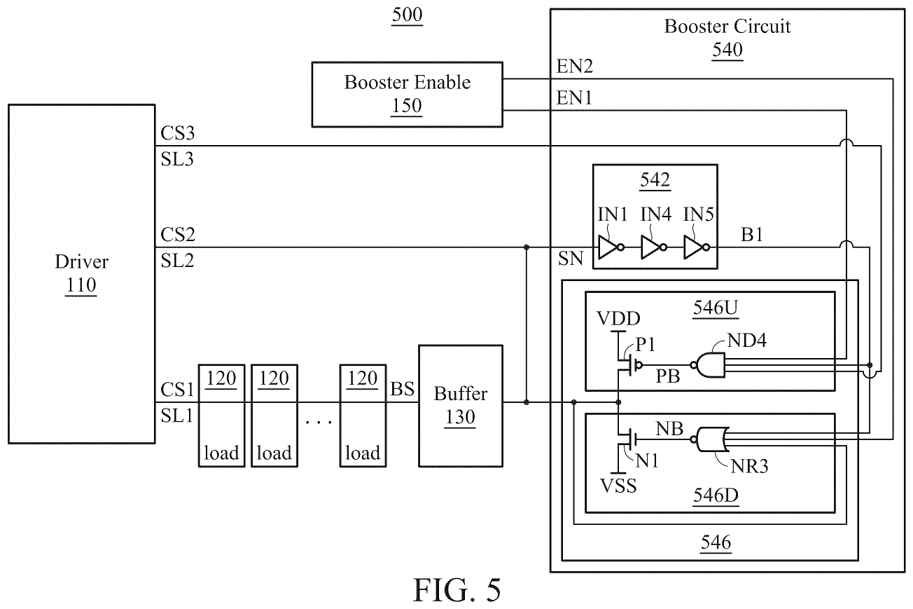

FIG. 5 is a schematic diagram of signal distribution circuit 500, in accordance with some embodiments. Signal distribution circuit 500, also referred to as circuit 500 in some embodiments, is usable as circuit 100 or 100M and includes driver 110, load circuits 120, buffer 130, and booster enable source 150, each discussed above with respect to FIGS. 1A and 1B.

Circuit 500 also includes booster circuit 540, usable as booster circuit 140, including delay stage 542, usable as delay stage 142, and boost stage 546, usable as boost stage 146, each discussed above with respect to FIGS. 1A and 1B.

As depicted in FIG. 5, delay stage 542 includes inverter IN1, discussed above with respect to FIGS. 2A-3, and inverters IN4 and IN5 arranged in series. Inverter IN5 includes an output terminal configured to output booster signal B1. In some embodiments, delay stage 542 includes inverter IN2, discussed above with respect to FIGS. 2A and 2B, instead of inverter IN1.

Boost stage 546 includes pull-up circuit 546U and pull-down circuit 546D, each coupled to node SN. Pull-up circuit 546U includes transistor P1 coupled to an output terminal of a NAND gate ND4, and pull-down circuit 546D includes transistor N1 coupled to an output terminal of a NOR gate NR3.

NAND gate ND4 of pull-up circuit 546U includes an input terminal configured to receive enable signal EN1, an input terminal coupled to the output terminal of inverter IN5 and thereby configured to receive booster signal B1, and an input terminal configured to receive control signal CS3. NAND gate ND4 is thereby configured to, in operation, output boost signal PB to the gate of transistor P1 responsive to enable signal EN1, booster signal B1, and control signal CS3, and transistor P1 is thereby configured to selectively couple and decouple node SN to and from power supply voltage node VDD responsive to boost signal PB.

NOR gate NR3 of pull-down circuit 546D includes an input terminal coupled to the output terminal of inverter IN5 and thereby configured to receive booster signal B1, an input terminal configured to receive enable signal EN2, and an input terminal coupled to node SN. NOR gate NR3 is thereby configured to output boost signal NB to the gate of transistor N1 responsive to booster signal B1, enable signal EN2, and control signal CS2 received from node SN, and transistor N1 is thereby configured to selectively couple and decouple node SN to and from reference voltage node VSS responsive to boost signal NB.

In the embodiment depicted in FIG. 5, driver 100 is configured to output control signals CS1-CS3 including trailing pulse edges synchronized with each other, each of the control signal CS2 pulse and the control signal CS3 pulse including the high logic level, e.g., being identical. In various embodiments, either the control signal CS1 pulse includes the low logic level and buffer 130 includes inverting logic, or the control signal CS1 pulse includes the high logic level and buffer 130 includes non-inverting logic.

Booster circuit 540 is thereby configured to, in operation, receive control signal CS2 at delay stage 542 and boost stage 546, control signal CS3 at pull-up circuit 546U of boost stage 546, enable signal EN1 at pull-up circuit 546U of boost stage 546, and enable signal EN2 at pull-down circuit 546D of boost stage 546, and to control coupling and decoupling of node SN to and from power supply voltage node VDD using pull-up circuit 546U and to and from reference voltage node VSS using pull-down circuit 546D responsive to control signals CS2 and CS3 and enable signals EN1 and EN2 in accordance with the discussion above with respect to circuits 100 and 100M and booster circuit 140.

Booster circuit 540, as included in circuit 500 in some embodiments, is thereby configured to realize the benefits discussed above with respect to circuits 100 and 100M and booster circuit 140. Compared to embodiments, e.g., those including booster circuit 240A, 240B, or 340 discussed above, in which control signals CS2 and CS3 do not each include the high logic level, e.g., are not identical, booster circuit 540 uses fewer logic gate components but requires a dedicated signal line SL3 not otherwise used in circuit 500.

FIG. 6 is a schematic diagram of signal distribution circuit 600, in accordance with some embodiments. Signal distribution circuit 600, also referred to as circuit 600 in some embodiments, is usable as circuit 100 or 100M and includes driver 110, load circuits 120, buffer 130, and booster enable source 150, each discussed above with respect to FIGS. 1A and 1B.

Circuit 600 also includes booster circuit 640, usable as booster circuit 140, including delay stage 642, usable as delay stage 142, and boost stage 646, usable as boost stage 146, each discussed above with respect to FIGS. 1A and 1B.

As depicted in FIG. 6, delay stage 642 includes inverter IN1, discussed above with respect to FIGS. 2A-3, and inverter IN4 arranged in series. Inverter IN4 includes an output terminal configured to output booster signal B1. In some embodiments, delay stage 642 includes inverter IN2, discussed above with respect to FIGS. 2A and 2B, instead of inverter IN1.

Boost stage 646 includes pull-up circuit 646U and pull-down circuit 646D, each coupled to node SN. Pull-up circuit 646U and pull-down circuit 646D collectively include a tri-state inverter IN6 including transistors P1 and N1 and additional transistors that are not shown in FIG. 6 for the purpose of clarity. The gate of transistor P1 of pull-up circuit 646U is coupled to an output terminal of a NAND gate ND5, and the gate of transistor N1 of pull-down circuit 646D is coupled to an output terminal of a NOR gate NR4.

NAND gate ND5 of pull-up circuit 646U includes an input terminal configured to receive enable signal EN1 and an input terminal coupled to node NS and thereby configured to receive control signal CS2. NAND gate ND5 is thereby configured to, in operation, output boost signal PB to the gate of transistor P1 responsive to enable signal EN1 and control signal CS2. The additional PMOS transistor of tri-state inverter IN6 includes a gate coupled to the output terminal of inverter IN4 and is thereby configured to receive booster signal B1. Tri-state inverter IN6 is thereby configured to, in operation, selectively couple and decouple node SN to and from power supply voltage node VDD through transistor P1 responsive to boost signal PB and the additional PMOS transistor responsive to booster signal B1.

NOR gate NR4 of pull-down circuit 646D includes an input terminal coupled to node NS and thereby configured to receive control signal CS2 and an input terminal configured to receive enable signal EN2. NOR gate NR4 is thereby configured to output boost signal PB to the gate of transistor N1 responsive to control signal CS2 and enable signal EN2. The additional NMOS transistor of tri-state inverter IN6 includes a gate coupled to the output terminal of inverter IN4 and is thereby configured to receive booster signal B1. Tri-state inverter IN6 is thereby configured to, in operation, selectively couple and decouple node SN to and from reference voltage node VSS through transistor N1 responsive to boost signal NB and the additional NMOS transistor responsive to booster signal B1.

In various embodiments, one or both of pull-up circuit 646U also includes PMOS transistors P3 and P4 coupled in series between the output terminal of NAND gate ND5 and power supply voltage node VDD, the gates of each of transistors P3 and P4 being coupled to the output terminal of NAND gate ND5, or pull-down circuit 646D also includes NMOS transistors N3 and N4 coupled in series between node NS and reference voltage node VSS, the gates of each of transistors N3 and N4 being coupled to node NS.

Transistors P3 and P4 and/or N3 and N4 are configured, e.g., as weak or slow transistors, such that in power-on operations, in embodiments including transistors P3 and P4, boost signal PB voltage changes are thereby slowed, and in embodiments including transistors N3 and N4, node SN voltage changes are thereby slowed, the likelihood of a power-on lockup scenario thereby being reduced by the presence of transistors P3 and P4 and/or N3 and N4.

In the embodiment depicted in FIG. 6, driver 100 is configured to output control signals CS1 and CS2 including trailing pulse edges synchronized with each other, the control signal CS2 pulse including the high logic level. In various embodiments, either the control signal CS1 pulse includes the low logic level and buffer 130 includes inverting logic, or the control signal CS1 pulse includes the high logic level and buffer 130 includes non-inverting logic.

Booster circuit 640 is thereby configured to, in operation, receive control signal CS2 at delay stage 642 and boost stage 646, enable signal EN1 at pull-up circuit 646U of boost stage 646, and enable signal EN2 at pull-down circuit 646D of boost stage 646, and to control coupling and decoupling of node SN to and from power supply voltage node VDD using pull-up circuit 646U and to and from reference voltage node VSS using pull-down circuit 646D responsive to control signal CS2 and enable signals EN1 and EN2 in accordance with the discussion above with respect to circuits 100 and 100M and booster circuit 140.

Booster circuit 640, as included in circuit 600 in some embodiments, is thereby configured to realize the benefits discussed above with respect to circuits 100 and 100M and booster circuit 140. Compared to embodiments, e.g., those including booster circuit 240A, 240B, 340, or 540 discussed above, that do not include transistors P3 and P4 and/or N3 and N4, booster circuit 640 requires fewer logic gate components and does not rely on receiving control signal CS3, but has reduced yield based on using transistors P3 and P4 and/or N3 and N4 instead of logic gates to avoid power-on lockup scenarios.

FIG. 7 is a flowchart of method 700 of operating a booster circuit, in accordance with some embodiments. Method 700, also referred to as a method 700 of operating a circuit in some embodiments, is usable with a booster circuit 140, 240A, 240B, 340, 500, or 600 discussed above with respect to FIGS. 1A-6.

The sequence in which the operations of method 700 are depicted in FIG. 7 is for illustration only; the operations of method 700 are capable of being executed in sequences that differ from that depicted in FIG. 7. In some embodiments, operations in addition to those depicted in FIG. 7 are performed before, between, during, and/or after the operations depicted in FIG. 7. In some embodiments, the operations of method 700 are a subset of a method of operating a signal distribution circuit, e.g., a circuit 100, 100M, 200A, 200B, 300, 500, or 600 discussed above.

At operation 702, in some embodiments, two or more control signals are output to first ends of corresponding signal lines. In some embodiments, outputting the two or more control signals to the first ends of the corresponding signal lines includes outputting control signals CS1, CS2, and in some embodiments CS3 from driver 110 or local control circuit 110M to signal lines SL1, SL2, and in some embodiments SL3, as discussed above with respect to FIGS. 1A-6.

At operation 704, a first control signal of the two or more control signals is received at a signal node of a booster circuit. In some embodiments, receiving the first control signal of the two or more control signals at the signal node of the booster circuit includes receiving control signal CS2 at signal node SN of booster circuit 140, 240A, 240B, 340, 540, or 640 as discussed above with respect to FIGS. 1A-6.

In some embodiments, receiving the first control signal of the two or more control signals at the signal node of the booster circuit includes receiving a second control signal of the two or more control signals at the booster circuit. In some embodiments, receiving the second control signal at the control circuit includes receiving control signal CS3 at booster circuit 140, 240A, 240B, 340, 540, or 640 as discussed above with respect to FIGS. 1A-6.

In some embodiments, receiving the first control signal of the two or more control signals at the signal node of the booster circuit includes receiving one or more enable signals at the booster circuit. In some embodiments, receiving the one or more enable signals at the control circuit includes receiving enable signal EN1 and in some embodiments enable signal EN2 at booster circuit 140, 240A, 240B, 340, 540, or 640 as discussed above with respect to FIGS. 1A-6.

At operation 706, a booster signal is output from a delay stage of the booster circuit in response to the first control signal. In some embodiments, outputting the booster signal from the delay stage includes outputting the booster signal as one of two booster signals output from the delay stage. In some embodiments, outputting the booster signal from the delay stage includes outputting one or both of booster signals B1 or B2 from delay stage 142, 242A, 242B, 542, or 642 as discussed above with respect to FIGS. 1A-6.

In some embodiments, outputting the booster signal from the delay stage includes receiving the booster signal and the second control signal at an inhibit circuit of the booster circuit, and outputting a third booster signal from the inhibit circuit. In some embodiments, receiving the booster signal and the second control signal at the inhibit circuit, and outputting the third booster signal from the inhibit circuit includes receiving booster signal B2 and control signal CS3 at, and outputting booster signal B3 from, inhibit circuit 144 or 244 as discussed above with respect to FIGS. 1A-2B.

In some embodiments, outputting the booster signal from the delay stage includes outputting a booster signal voltage transition delayed from a first control signal voltage transition. In some embodiments, outputting the booster signal voltage transition delayed from the first control signal voltage transition includes outputting one or more voltage transitions in one or more of booster signals B1-B3 delayed from a voltage transition in control signal CS2 as discussed above with respect to FIGS. 1A-6.

At operation 708, in response to the first control signal and the booster signal, a boost stage of the control circuit is used to selectively couple the signal node to each of a power supply voltage node and a reference voltage node. In some embodiments, using the boost stage to selectively couple the signal node to each of the power supply voltage node and the reference voltage node in response to the first control signal and the booster signal includes using boost stage 146, 246, 346, 546, or 646 to selectively couple node SN to each of power supply voltage node VDD and reference voltage node VSS in response to one or more of boost signals B1-B3 and control signal CS2, as discussed above with respect to FIGS. 1A-6.

In some embodiments, using the boost stage to selectively couple the signal node to the power supply voltage node includes outputting a first boost signal to a first PMOS transistor of a pull-up circuit to selectively couple the signal node to the power supply voltage node. In some embodiments, outputting the first boost signal to the first PMOS transistor of the pull-up circuit to selectively couple the signal node to the power supply voltage node includes outputting boost signal PB to transistor P1 of pull-up circuit 146U, 246U, 346U, 546U, or 646U to selectively couple node SN to power supply voltage node VDD as discussed above with respect to FIGS. 1A-6.

In some embodiments, using the boost stage to selectively couple the signal node to the reference voltage node includes outputting a second boost signal to a first NMOS transistor of a pull-down circuit to selectively couple the signal node to the reference voltage node. In some embodiments, outputting the second boost signal to the first NMOS transistor of the pull-down circuit to selectively couple the signal node to the reference voltage node includes outputting boost signal NB to transistor N1 of pull-down circuit 146D, 246D, 346D, 546D, or 646D to selectively couple node SN to reference voltage node VSS as discussed above with respect to FIGS. 1A-6.

In some embodiments, using the boost stage to selectively couple the signal node to each of the power supply voltage node and the reference voltage node in response to the first control signal and the booster signal includes using the boost stage to selectively decouple the signal node to each of the power supply voltage node and the reference voltage node in response to the first control signal and the booster signal. In some embodiments, using the boost stage to selectively decouple the signal node from each of the power supply voltage node and the reference voltage node in response to the first control signal and the booster signal includes using boost stage 146, 246, 346, 546, or 646 to selectively decouple node SN from each of power supply voltage node VDD and reference voltage node VSS in response to one or more of boost signals B1-B3 and control signal CS2, as discussed above with respect to FIGS. 1A-6.

In some embodiments, using the boost stage to selectively couple the signal node to each of the power supply voltage node and the reference voltage node in response to the first control signal and the booster signal includes using the boost stage to selectively decouple the signal node from one of the power supply voltage node or the reference voltage node in response to the second control signal. In some embodiments, using the boost stage to selectively decouple the signal node from one of the power supply voltage node or the reference voltage node in response to the second control signal includes using transistor P2 or N2 of boost stage 346 to selectively decouple node SN from the corresponding one of power supply voltage node VDD or reference voltage node VSS in response to control signal CS3, as discussed above with respect to FIG. 3.

In some embodiments, using the boost stage to selectively couple the signal node to each of the power supply and reference voltage nodes includes coupling the signal node to one of the power supply or reference voltage node in response to the first control signal voltage transition and coupling the signal node to the other of the power supply or reference voltage node in response to the booster signal voltage transition. In some embodiments, coupling the signal node to the one of the power supply or reference voltage node in response to the first control signal voltage transition and coupling the signal node to the other of the power supply or reference voltage node in response to the booster signal voltage transition includes coupling signal node SN to the one of power supply voltage node VDD or reference voltage node VSS in response to a control signal CS2 voltage transition and coupling signal node SN to the other of power supply voltage node VDD or reference voltage node VSS in response to a voltage transition in one of booster signals B1-B3 as discussed above with respect to FIGS. 1A-6.

In some embodiments, in response to a voltage transition in the second control signal, using the boost stage to couple the signal node to the other of the power supply or reference voltage node. In some embodiments, using the boost stage to couple the signal node to the other of the power supply or reference voltage node in response to the voltage transition in the second control signal includes using boost stage 146, 246, 346, 546, or 646 to couple node SN to the other of power supply voltage node VDD or reference voltage node VSS in response to a voltage transition in control signal CS3 as discussed above with respect to FIGS. 1A-6.

In some embodiments, in response to the one or more enable signals, disabling selectively coupling the signal node to each of the power supply and reference voltage nodes. In some embodiments, disabling selectively coupling the signal node to each of the power supply and reference voltage nodes in response to the one or more enable signals includes disabling selectively coupling node NS to each of power supply voltage node VDD and reference voltage node VSS in response to enable signal EN1 and in some embodiments EN2.

In some embodiments, using the boost stage to selectively couple the signal node to each of the power supply voltage node and the reference voltage node includes using the boost stage to selectively couple an input terminal of a buffer to each of the power supply voltage node and the reference voltage node, the buffer including an output terminal coupled to a second end of the second signal line. In some embodiments, using the boost stage to selectively couple the input terminal of the buffer to each of the power supply voltage node and the reference voltage node, the buffer including the output terminal coupled to the second end of the second signal line includes using boost stage 146, 246, 346, 546, or 646 to selectively couple an input terminal of buffer 130 or 130M to each of power supply voltage node VDD and reference voltage node VSS, buffer 130 or 130M including an output terminal coupled to a second end of signal line SL1.

By executing some or all of the operations of method 700, a booster circuit controls coupling a node to power supply and reference voltage nodes in response to one or more received control signals, thereby achieving the benefits discussed above with respect to control circuits 140, 240A, 240B, 300, 540, and 640, and in some embodiments, circuits 100, 100M, 200A, 200B, 300, 500, and 600.

In some embodiments, a circuit includes a signal node configured to receive a first control signal, a delay stage coupled to the signal node and configured to output a first booster signal responsive to the first control signal, and a boost stage coupled to the signal node and the delay stage, wherein the boost stage includes a pull-up circuit including a first transistor configured to couple the signal node to a power supply voltage node responsive to the first booster signal and a pull-down circuit including a second transistor configured to couple the signal node to a reference voltage node responsive to the first booster signal. In some embodiments, the delay stage includes a first inverter including an input terminal coupled to the signal node, a first NAND gate including a first input terminal configured to receive an enable signal, a second input terminal coupled to an output terminal of the first inverter, and an output terminal configured to output the first booster signal, and a second NAND gate including a first input terminal coupled to the output terminal of the first NAND gate, a second input terminal configured to receive the enable signal, and an output terminal, the pull-up circuit includes a third NAND gate including a first input terminal configured to receive a second booster signal based on the first booster signal, a second input terminal coupled to the signal node, and an output terminal coupled to a gate of the first transistor, and the pull-down circuit includes a first NOR gate including a first input terminal coupled to the output terminal of the second NAND gate, a second input terminal coupled to the signal node, and an output terminal coupled to a gate of the second transistor. In some embodiments, the circuit includes a second NOR gate including a first input terminal coupled to the output terminal of the first NAND gate, a second input terminal configured to receive a second control signal, and an output terminal coupled to the first input terminal of third NAND gate. In some embodiments, the first inverter includes a Schmitt trigger. In some embodiments, the circuit includes a second inverter including an input terminal coupled to the output terminal of the first NAND gate, and an output terminal coupled to the first input terminal of the third NAND gate, wherein the boost stage includes a third transistor either in series with the first transistor or in series with the second transistor, and the third transistor includes a gate configured to receive a second control signal. In some embodiments, the delay stage includes first through third inverters coupled in series between the signal node and the boost stage, the pull-up circuit includes a NAND gate including a first input terminal configured to receive a first enable signal, a second input terminal coupled to an output terminal of the third inverter, a third input terminal configured to receive a second control signal, and an output terminal coupled to a gate of the first transistor, and the pull-down circuit includes a NOR gate including a first input terminal coupled to the output terminal of the third inverter, a second input terminal configured to receive a second enable signal, a third input terminal coupled to the signal node, and an output terminal coupled to a gate of the second transistor. In some embodiments, the delay stage includes first and second inverters coupled in series between the signal node and the boost stage, and the boost stage includes a NAND gate including a first input terminal configured to receive a first enable signal, a second input terminal coupled to the signal node, and an output terminal, a NOR gate including a first input terminal coupled to the signal node, a second input terminal configured to receive a second enable signal, and an output terminal, a tri-state inverter including the first and second transistors, an input terminal coupled to an output terminal of the second inverter, a first enable terminal coupled to the output terminal of the NAND gate, a second enable terminal coupled to the output terminal of the NOR gate, and an output terminal coupled to the signal node, and one or both of third and fourth transistors coupled between the output terminal of the NAND gate and the power supply voltage node, or fifth and sixth transistors coupled between the signal node and the reference voltage node. In some embodiments, the signal node is coupled to a sense amplifier enable (SAE) distribution path of a memory circuit, and the first control signal includes a SAE signal.

In some embodiments, a circuit includes first and second signal lines, a driver coupled to first ends of the first and second signal lines and configured to output respective first and second control signals to the first and second signal lines, a booster circuit coupled to a second end of the first signal line, and a buffer coupled between a second end of the second signal line and the booster circuit, wherein the booster circuit includes a delay stage configured to output a first booster signal responsive to the first control signal received at the second end of the first signal line, and a boost stage coupled to the delay stage, wherein the boost stage includes a pull-up circuit configured to couple an input terminal of the buffer to a power supply voltage node responsive to the first booster signal, and a pull-down circuit configured to couple the input terminal of the buffer to a reference voltage node responsive to the first booster signal. In some embodiments, the circuit includes a third signal line coupled between the driver and the booster circuit, wherein the driver is configured to output a third control signal to the third signal line, and the pull-up circuit is configured to couple the input terminal of the buffer to the power supply voltage node further responsive to the third control signal. In some embodiments, the driver is configured to output the third control signal including a pulse edge synchronized with a pulse edge of the first control signal, and the booster circuit is configured to decouple the input terminal of the buffer from the power supply voltage node responsive to the pulse edge of the third control signal. In some embodiments, the booster circuit is configured to cause the boost stage to couple the input terminal of the buffer to the power supply and reference voltage nodes further responsive to an enable signal. In some embodiments, the pull-up circuit includes a NAND gate including an input terminal coupled to the input terminal of the buffer, and the pull-down circuit includes a NOR gate including an input terminal coupled to the input terminal of the buffer. In some embodiments, the buffer includes an inverter. In some embodiments, the circuit includes a plurality of load circuits coupled to the second signal line between the driver and an output terminal of the buffer, wherein each load circuit of the plurality of load circuits is configured to receive the second control signal. In some embodiments, the driver includes a control circuit of an SRAM circuit, the plurality of load circuits includes a plurality of sense amplifier circuits, and the second control signal includes a sense amplifier enable signal.

In some embodiments, a method of operating a circuit includes receiving a first control signal at a signal node of a booster circuit, outputting, from a delay stage of the booster circuit, a booster signal in response to the first control signal, and in response to the first control signal and the booster signal, using a boost stage of the control circuit to selectively couple the signal node to each of a power supply voltage node and a reference voltage node. In some embodiments, outputting the booster signal includes outputting a booster signal voltage transition delayed from a first control signal voltage transition, and using the boost stage to selectively couple the signal node to each of the power supply and reference voltage nodes includes coupling the signal node to one of the power supply or reference voltage node in response to the first control signal voltage transition and coupling the signal node to the other of the power supply or reference voltage node in response to the booster signal voltage transition. In some embodiments, the method includes receiving a second control signal at the booster circuit, and in response to a second control circuit voltage transition, using the boost stage to couple the signal node to the other of the power supply or reference voltage node. In some embodiments, the method includes receiving an enable signal at the booster circuit, and in response to the enable signal, disabling selectively coupling the signal node to each of the power supply and reference voltage nodes.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit comprising:
a signal node configured to receive a first control signal;
a delay stage coupled to the signal node and configured to output a first booster signal responsive to the first control signal; and
a boost stage coupled to the signal node and the delay stage, wherein the boost stage comprises:
a pull-up circuit comprising a first transistor configured to couple the signal node to a power supply voltage node responsive to the first booster signal; and
a pull-down circuit comprising a second transistor configured to couple the signal node to a reference voltage node responsive to the first booster signal.

2. The circuit of claim 1, wherein
the delay stage comprises:
a first inverter comprising an input terminal coupled to the signal node;
a first NAND gate comprising:
a first input terminal configured to receive an enable signal;
a second input terminal coupled to an output terminal of the first inverter; and
an output terminal configured to output the first booster signal; and
a second NAND gate comprising:
a first input terminal coupled to the output terminal of the first NAND gate;
a second input terminal configured to receive the enable signal; and
an output terminal,
the pull-up circuit further comprises a third NAND gate comprising:
a first input terminal configured to receive a second booster signal based on the first booster signal;
a second input terminal coupled to the signal node; and
an output terminal coupled to a gate of the first transistor, and
the pull-down circuit further comprises a first NOR gate comprising:
a first input terminal coupled to the output terminal of the second NAND gate;
a second input terminal coupled to the signal node; and
an output terminal coupled to a gate of the second transistor.

3. The circuit of claim 2, further comprising:
a second NOR gate comprising:
a first input terminal coupled to the output terminal of the first NAND gate;
a second input terminal configured to receive a second control signal; and
an output terminal coupled to the first input terminal of third NAND gate.

4. The circuit of claim 3, wherein
the first inverter comprises a Schmitt trigger.

5. The circuit of claim 2, further comprising:
a second inverter comprising:
an input terminal coupled to the output terminal of the first NAND gate; and
an output terminal coupled to the first input terminal of the third NAND gate, wherein
the boost stage comprises a third transistor either in series with the first transistor or in series with the second transistor, and
the third transistor comprises a gate configured to receive a second control signal.

6. The circuit of claim 1, wherein
the delay stage comprises first through third inverters coupled in series between the signal node and the boost stage,
the pull-up circuit comprises a NAND gate comprising:
a first input terminal configured to receive a first enable signal;
a second input terminal coupled to an output terminal of the third inverter;
a third input terminal configured to receive a second control signal; and
an output terminal coupled to a gate of the first transistor, and
the pull-down circuit comprises a NOR gate comprising:
a first input terminal coupled to the output terminal of the third inverter;
a second input terminal configured to receive a second enable signal;
a third input terminal coupled to the signal node; and
an output terminal coupled to a gate of the second transistor.

7. The circuit of claim 1, wherein
the delay stage comprises first and second inverters coupled in series between the signal node and the boost stage, and
the boost stage comprises:
a NAND gate comprising:
a first input terminal configured to receive a first enable signal;
a second input terminal coupled to the signal node; and
an output terminal;
a NOR gate comprising:
a first input terminal coupled to the signal node;
a second input terminal configured to receive a second enable signal; and
an output terminal;
a tri-state inverter comprising:
the first and second transistors;
an input terminal coupled to an output terminal of the second inverter;
a first enable terminal coupled to the output terminal of the NAND gate;
a second enable terminal coupled to the output terminal of the NOR gate; and
an output terminal coupled to the signal node; and
one or both of:
third and fourth transistors coupled between the output terminal of the NAND gate and the power supply voltage node; or
fifth and sixth transistors coupled between the signal node and the reference voltage node.

8. The circuit of claim 1, wherein
the signal node is coupled to a sense amplifier enable (SAE) distribution path of a memory circuit, and
the first control signal comprises a SAE signal.

9. A circuit comprising:
first and second signal lines;
a driver coupled to first ends of the first and second signal lines and configured to output respective first and second control signals to the first and second signal lines;
a booster circuit coupled to a second end of the first signal line; and
a buffer coupled between a second end of the second signal line and the booster circuit,
wherein the booster circuit comprises:
a delay stage configured to output a first booster signal responsive to the first control signal received at the second end of the first signal line; and
a boost stage coupled to the delay stage, wherein the boost stage comprises:
a pull-up circuit configured to couple an input terminal of the buffer to a power supply voltage node responsive to the first booster signal; and
a pull-down circuit configured to couple the input terminal of the buffer to a reference voltage node responsive to the first booster signal.

10. The circuit of claim 9, further comprising:
a third signal line coupled between the driver and the booster circuit,
wherein
the driver is configured to output a third control signal to the third signal line, and
the pull-up circuit is configured to couple the input terminal of the buffer to the power supply voltage node further responsive to the third control signal.

11. The circuit of claim 10, wherein
the driver is configured to output the third control signal comprising a pulse edge synchronized with a pulse edge of the first control signal, and
the booster circuit is configured to decouple the input terminal of the buffer from the power supply voltage node responsive to the pulse edge of the third control signal.

12. The circuit of claim 9, wherein
the booster circuit is configured to cause the boost stage to couple the input terminal of the buffer to the power supply and reference voltage nodes further responsive to an enable signal.

13. The circuit of claim 9, wherein
the pull-up circuit comprises a NAND gate comprising an input terminal coupled to the input terminal of the buffer; and
the pull-down circuit comprises a NOR gate comprising an input terminal coupled to the input terminal of the buffer.

14. The circuit of claim 9, wherein
the buffer comprises an inverter.

15. The circuit of claim 9, further comprising:
a plurality of load circuits coupled to the second signal line between the driver and an output terminal of the buffer,
wherein each load circuit of the plurality of load circuits is configured to receive the second control signal.

16. The circuit of claim 15, wherein
the driver comprises a control circuit of a static random-access memory (SRAM) circuit,
the plurality of load circuits comprises a plurality of sense amplifier circuits, and
the second control signal comprises a sense amplifier enable signal.

17. A method of operating a circuit, the method comprising:
receiving a first control signal at a signal node of a booster circuit;
outputting, from a delay stage of the booster circuit, a booster signal in response to the first control signal; and
in response to the first control signal and the booster signal, using a boost stage of the control circuit to selectively couple the signal node to each of a power supply voltage node and a reference voltage node.

18. The method of claim 17, wherein
the outputting the booster signal comprises outputting a booster signal voltage transition delayed from a first control signal voltage transition, and
the using the boost stage to selectively couple the signal node to each of the power supply and reference voltage nodes comprises coupling the signal node to one of the power supply or reference voltage node in response to the first control signal voltage transition and coupling the signal node to the other of the power supply or reference voltage node in response to the booster signal voltage transition.

19. The method of claim 18, further comprising:
receiving a second control signal at the booster circuit; and
in response to a second control circuit voltage transition, using the boost stage to couple the signal node to the other of the power supply or reference voltage node.

20. The method of claim 17, further comprising:
receiving an enable signal at the booster circuit; and
in response to the enable signal, disabling the selectively coupling the signal node to each of the power supply and reference voltage nodes.
